(19) United States
(12) Patent Application Publication
(10) Pub. No.: US 2016/0231387 A1
(43) Pub. Date: Aug. 11, 2016

(54) Estimating Battery Cell Parameters

(71) Applicant: Microsoft Microsoft Technology Licensing, LLC, Redmond, WA (US)

(72) Inventors: Stephen E. Hodges, Cambridge (GB); Ranveer Chandra, Bellevue, WA (US); Julia L. Meinershagen, Seattle, WA (US); Nissanka Arachchige Bodhi Priyantha, Redmond, WA (US); Anirudh Badam, Redmond, WA (US); Thomas Moscibroda, Beijing (CN); Anthony John Ferrese, Berkeley, CA (US); Pan Hu, Amherst, MA (US); Evangelia Skiani, New York, NY (US)

(21) Appl. No.: 14/617,751

(22) Filed: Feb. 9, 2015

(51) Int. Cl. G01R 31/36

(52) U.S. Cl. CPC G01R 31/3662; G01R 31/3658; G01R 31/3648

(57) ABSTRACT

This document describes techniques and apparatuses for estimating battery cell parameters. In some embodiments, these techniques and apparatuses enable the isolation of a battery cell from other battery cells. Voltage levels of the isolated battery cell are measured while varying amounts of current are drawn from the cell. Parameters of the isolated battery cell can then be estimated based on the measured voltage levels and various amounts of current that are drawn from the cell.

### BACKGROUND

This background is provided for the purpose of generally presenting a context for the instant disclosure. Unless otherwise indicated herein, material described in the background is neither expressly nor impliedly admitted to be prior art to the instant disclosure or the claims that follow.

Batteries are often used as a power source for mobile computing and electronic devices. Typically, a run-time of the mobile device is determined by a capacity of the device's batteries, from which power is drawn until the batteries are unable to support operations of the mobile device. In most cases, an estimation of run-time or remaining battery capacity is displayed to a user of the device to inform the user of an expectation of device availability or need to recharge the device.

These estimations of run-time, an effective battery capacity, or other battery-related characteristics, however, are often inaccurate due to the dynamic variability of not only properties of the batteries, but the ways in which the mobile device draws power. Additionally, once manufactured into a mobile device, retrieving real-time information on the characteristics of a battery is often precluded by simplicity of traditional battery interface circuitry. Accordingly, the inaccurate estimation of run-time or effective battery capacity can adversely affect user experience when a mobile device unexpectedly resets or shuts down due to a battery's inability to provide sufficient power for the operations of the device.

### SUMMARY

This document describes techniques and apparatuses for estimating battery cell parameters. The estimated battery parameters can be used to build or update a model of the battery cell, which can be leveraged to optimize energy extraction from the battery cell. By so doing, energy stored in the battery cell can be used more efficiently to extend a run-time of a device drawing power from the battery cell. In some embodiments, voltage of a battery cell is measured while two different amounts of current are drawn from the battery cell. An internal resistance of the battery cell is then estimated based on the amounts of current drawn and the measured voltages of the battery cell. In other embodiments, voltage of battery cell is measured when an application load current to the battery cell is interrupted and at a later point in time when the voltage relaxes after the interruption. A capacitance or concentration resistance of the battery cell is then estimated based on the load current and the measured voltages of the battery cell. In these or other embodiments, the battery cell for which parameters are estimated may be isolated from other battery cells of a device or be a device's sole battery cell.

This summary is provided to introduce simplified concepts that are further described below in the Detailed Description. This summary is not intended to identify essential features of the claimed subject matter, nor is it intended for use in determining the scope of the claimed subject matter. Techniques and/or apparatuses for estimating battery parameters are also referred to herein separately or in conjunction as the “techniques” as permitted by the context, though techniques may include or instead represent other aspects described herein.

### BRIEF DESCRIPTION OF THE DRAWINGS

Embodiments enabling estimation of battery parameters are described with reference to the following drawings. The same numbers are used throughout the drawings to reference like features and components:

FIG. 1 illustrates an example environment in which techniques for estimating battery parameters can be implemented.

FIG. 2 illustrates an example battery system capable of implementing estimation of battery parameters.

FIG. 3 illustrates an example battery cell configuration in accordance with one or more embodiments.

FIG. 4 illustrates an example method for estimating internal resistance of a battery cell.

FIG. 5 illustrates an example discharge current profile and associated voltage measurements.

FIG. 6 illustrates an example charge current profile and associated voltage measurements.

FIG. 7 illustrates an example method for estimating capacitance or concentration resistance of a battery cell.

FIG. 8 illustrates example relaxation voltage profiles for various amounts of discharge current.

FIG. 9 illustrates example relaxation voltage profiles for various amounts of charge current.

FIG. 10 illustrates example models for estimating open circuit potential of a battery cell based on discharge data.

FIG. 11 illustrates comparisons of experimental data and model data for estimating open circuit potential after battery discharge.

FIG. 12 illustrates example models for estimating open circuit potential of a battery cell based on charging data.

FIG. 13 illustrates comparisons of experimental data and model data for estimating open circuit potential after battery charging.

FIG. 14 illustrates an example method of calculating parameters for multiple batteries.

FIG. 15 illustrates an example device in which techniques of estimating battery parameters can be implemented.

### DETAILED DESCRIPTION

### Overview

This document describes techniques and apparatuses for estimating battery cell parameters. These apparatuses and techniques may enable estimation of battery parameters such as internal resistance, capacitance, or concentration resistance, which effect a battery cell's ability to provide power. The estimated battery parameters can then be used to construct or update a model of the battery cell that more-accurately reflects or predicts the battery cell's future performance under various conditions. In some embodiments, these techniques and apparatuses enable estimation of a battery cell's internal resistance based on amounts of current drawn from, or applied to, the battery cell and respective voltage measurements made therewith. The techniques and apparatuses may also enable estimation of a battery cell's capacitance or concentration resistance based on an amount of current drawn from, or applied to, the battery cell and voltage measurements made after the application of current is interrupted. Further, the techniques and apparatuses may also isolate a battery cell from other battery cells in order to enable the estimation of battery parameters. These are but a few examples of many ways in which the techniques estimation of battery parameters, others of which are described below.

Example Operating Environment

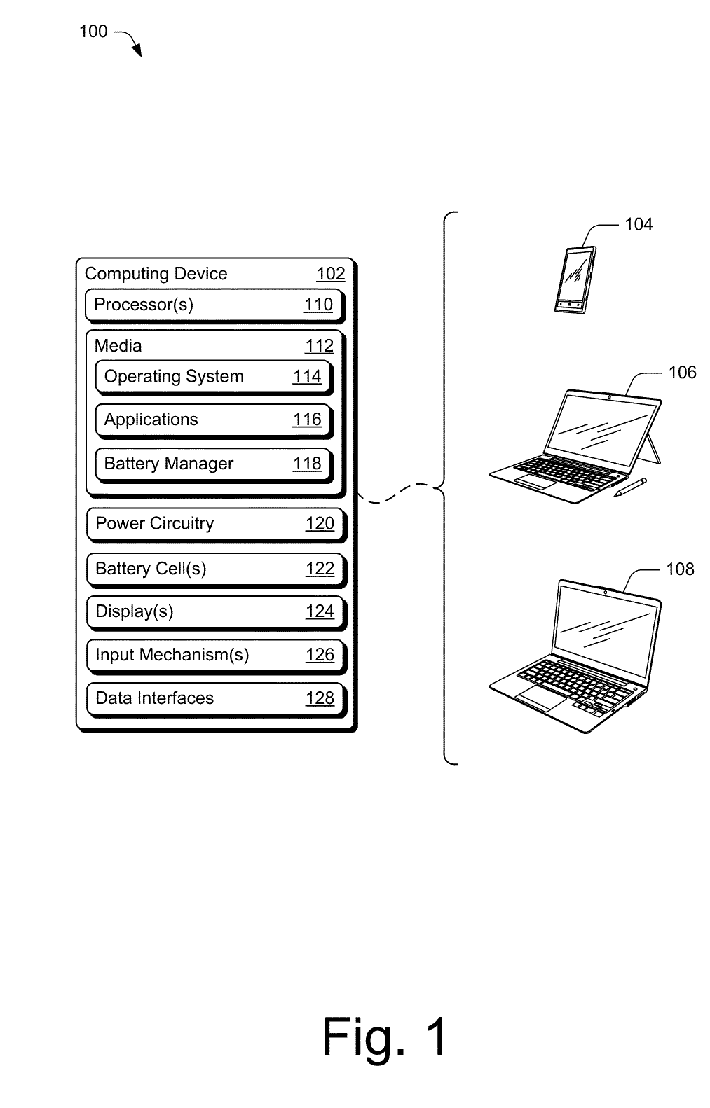

FIG. 1 illustrates an example operating environment 100 in which techniques for estimating battery parameters can be embodied. Operating environment 100 includes a computing device 102, which is illustrated with three examples: a smart phone computer 104, a tablet computing device 106, and a laptop computer 108, though other computing devices and systems, such as netbooks, smart watches, fitness accessories, electric vehicles, Internet-of-Things (IoT) devices, wearable computing devices, media players, and personal navigation devices may also be used.

Computing device 102 includes computer processor(s) 110 and computer-readable storage media 112 (media 112). Media 112 includes an operating system 114 and applications 116, which enable various operations of computing device 102. Operating system 114 manages resources of computing device 102, such as processor 110, media 112, and the like (e.g., hardware subsystems). Applications 116 comprise tasks or threads that access the resources managed by operating system 114 to implement various operations of computing device 102. Media 112 also includes battery manager 132, the implementation and use of which varies and is described in greater detail below.

Computing device 102 also includes power circuitry 120 and battery cell(s) 122, from which computing device 102 can draw power to operate. Generally, power circuitry 120 may include firmware or hardware configured to enable computing device 102 to draw operating power from battery cells 122 or to apply charging power to battery cells 122. Battery cells 122 may include any suitable number or type of rechargeable battery cells, such as lithium-ion (Lion), lithium-polymer (Li-Poly), lithium ceramic (Li-C), and the like. Implementations and uses of power circuitry 120 and battery cells 122 vary and are described in greater detail below.

Computing device 102 may also include display 124, input mechanisms 126, and data interfaces 128. Although shown integrated with the example devices of FIG. 1, display 124 may be implemented separate from computing device 102 via a wired or wireless display interface. Input mechanisms 126 may include gesture-sensitive sensors and devices, such as touch-based sensors and movement-tracking sensors (e.g., camera-based), buttons, touch pads, accelerometers, and microphones with accompanying voice recognition software, to name a few. In some cases, input mechanisms 126 are integrated with display 124, such an in a touch-sensitive display with integrated touch-sensitive or motion-sensitive sensors.

Data interfaces 128 include any suitable wired or wireless data interfaces that enable computing device 102 to communicate data with other devices or networks. Wired data interfaces may include serial or parallel communication interfaces, such as a universal serial bus (USB) and local-area-network (LAN). Wireless data interfaces may include transceivers or modules configured to communicate via infrastructure or peer-to-peer networks. One or more of these wireless data interfaces may be configured to communicate via near-field communication (NFC), a personal-area-network (PAN), a wireless local-area-network (WLAN), or wireless wide-area-network (WWAN). In some cases, operating system 114 or a communication manager (not shown) of computing device 102 selects a data interface for communications based on characteristics of an environment in which computing device 102 operates.

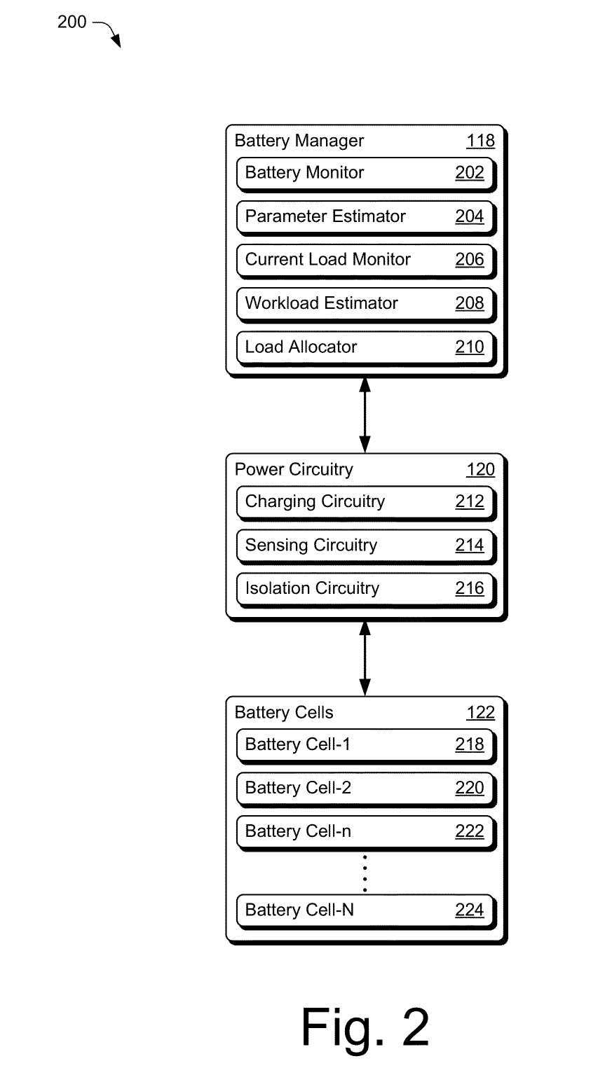

FIG. 2 illustrates an example battery system 200 capable of implementing aspects of the techniques described herein. In this particular example, battery system 200 includes battery manager 118, power circuitry 120, and battery cells 122. In some embodiments, battery manager is implemented in software (e.g., application programming interface) or firmware of a computing device by a processor executing processor-executable instructions. Alternately or additionally, components of battery manager 118 can be implemented integral with other components of battery system 200, such as power circuitry 120 and battery cells 122 (individual or packaged).

Battery manager 118 may include any or all of the entities shown in FIG. 2, which include battery monitor 202, parameter estimator 204, current load monitor 206, workload estimator 208, and load allocator 210. Battery monitor 202 is configured to monitor characteristics of battery cells 122, such as voltage, current flow, remaining capacity (e.g., state-of-charge), full charge capacity (which decreases as cycle count increases), temperature, age (e.g., time or charging cycles), and the like. Battery monitor 202 may also determine or have access to respective configuration information for battery cells 122, such as cell manufacturer, chemistry type, rated capacity, voltage and current limits (e.g., cutoffs), and the like. Battery monitor 202 may store and enable other entities of battery manager 118 to access this battery cell configuration information.

Parameter estimator 204 is configured to estimate parameters of battery cells 122, such as internal resistance, capacitance, or concentration resistance. In some cases, parameter estimator estimates these parameters based on characteristics of the battery cells that are monitored by battery monitor 202, such as current flow and voltage. The implementation and use of battery monitor 202 varies and is described below in greater detail.

Current load monitor 206 monitors an amount of current drawn from one or more of battery cells 122 by computing device 102. In some cases, current load monitor 206 monitors individual amounts of current drawn from each respective one of battery cells 122. Current load monitor 206 may also monitor an amount of current applied to one or more of battery cells 122 by computing device 102 during charging. In at least some embodiments, current load monitor 206 provides real-time information indicating an amount of current drawn from a battery cell, such as at a rate on the order of milliseconds or seconds.

Workload estimator 208 estimates an amount of current that may be consumed when computing device 102 performs various tasks or operations. The estimated amount of current may be based on tasks that computing device 102 is performing, scheduled to perform, likely to perform, and so on. For example, workload estimator may receive information from operating system 114 that indicates a set of tasks are scheduled for execution by resources of computing device 102. Workload estimator 208 may also include or have access to information that describes relationships between power consumption of hardware components and their respective workloads. Based on the set of tasks, workload estimator 208 estimates or forecasts an amount of current that computing device 102 will consume to perform the tasks. In some cases, workload estimator 208 provides a current consumption forecast over time based on a schedule or predicted order of execution for the tasks.

Load allocator 210 is configured to determine an amount of current to draw from each battery cell 122. In some cases, load allocator 210 determines a load allocation scheme based on information received from other entities of battery manager 118, such as current and forecast power demands of computing device 102, and respective characteristics, states-of-charge, internal resistances for battery cells 122. A load allocation may be configured to draw power from all or a subset of battery cells 122 based on the aforementioned information to maximize an efficiency of drawing power from multiple battery cells.

Although shown as disparate entities, any or all of battery monitor 202, parameter estimator 204, current load monitor 206, workload estimator 208, and load allocator 210 may be implemented separate from each other or combined or integrated in any suitable form. For example, any of these entities, or functions thereof, may be combined generally as battery manager 118, which can be implemented as a program application interface (API) or system component of operating system 114.

Battery system 200 also includes power circuitry 120, which provides an interface between battery manager 118 and battery cells 122. Generally, power circuitry 120 may include hardware and firmware that enables computing device 102 to draw power from (e.g., discharge), apply power to (e.g., charge) battery cells 122, and implement various embodiments thereof. In this particular example, power circuitry 120 includes charging circuitry 212, sensing circuitry 214, and isolation circuitry 216.

Charging circuitry 120 is configured to provide current by which battery cells 122 are charged. Charging circuitry may implement any suitable charging profile such as constant current, constant voltage, custom profiles provided by battery manager 118, and the like. In at least some embodiments, charging circuitry 212 is capable of providing different amounts of current to different respective battery cells being charged concurrently.

Sensing circuitry 214 is configured to sense or monitor operational characteristics of battery cells 122. These operational characteristics may include a voltage level, an amount of current applied to, or an amount of current drawn from a respective one of battery cells 122. In some cases, sensing circuitry 214 may be implemented integral with charging circuitry 120, such as part of a charging controller or circuit that includes sensing elements (e.g., analog-to-digital converters (ADCs), amplifiers, and sense resistors).

Power circuitry 120 also includes isolation circuitry 216, which enables battery manager 118 to isolate single or subsets of battery cells 122. While isolated, single battery cells or subsets of battery cells may be charged or discharged concurrently. For example, charging current can be applied to a battery cell isolated by isolation circuitry 216 while computing device 102 draws operating power from all or a subset of the remaining battery cells. In some cases, isolation circuitry is implemented as multiplexing circuitry that switches between battery cells 122 to facilitate connection with an appropriate set of power circuitry for battery cell sensing, current consumption, or current application.

Battery cells 122 may include any suitable number or type of battery cells. In this particular example, battery cells 122 include battery cell 1 218, battery cell 2 220, battery cell n 222, and battery cell N 224, where N may be any suitable integer. In some cases, computing device may include a single battery cell 122 to which the techniques described herein can be applied without departing from the spirit of the disclosure. In other cases, battery cells 122 may include various homogeneous or heterogeneous combinations of cell shape, capacity, or chemistry type.

Example types of battery chemistry may include lithium-ion, lithium-polymer, lithium ceramic, flexible printed circuit Li-C (FPC-LiC), and the like. Each of battery cells 122 may have a particular or different cell configuration, such as a chemistry type, shape, capacity, packaging, electrode size or shape, series or parallel cell arrangement, and the like. Accordingly, each of battery cells 122 may also have different parameters, such as internal resistance, capacitance, or concentration resistance.

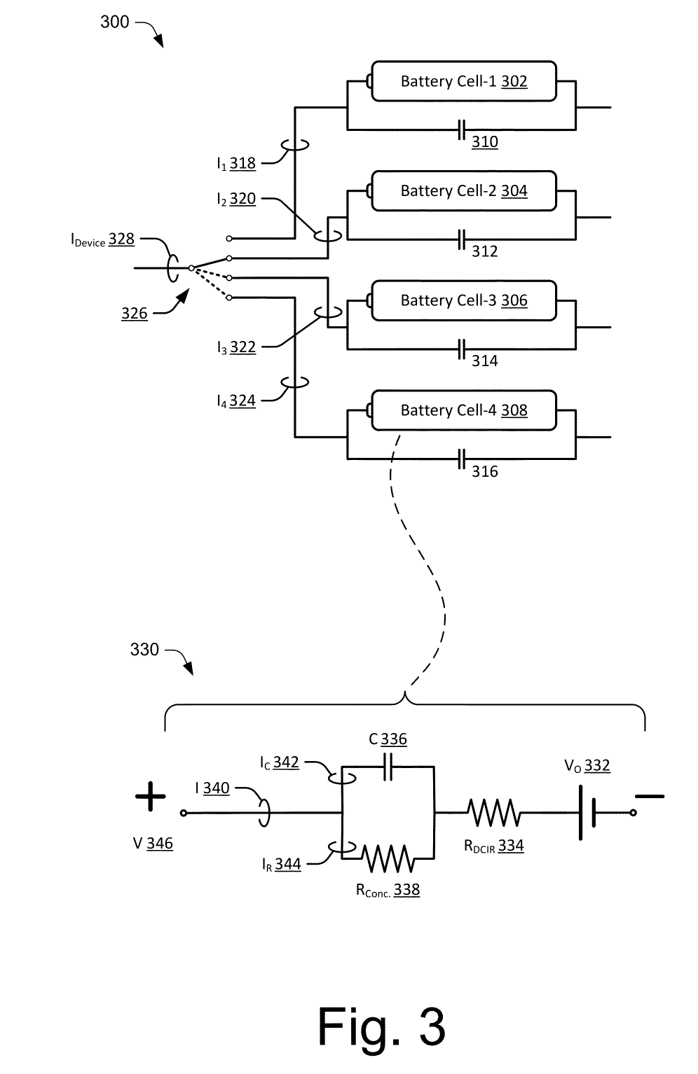

FIG. 3. Illustrates an example battery cell configuration 300 in accordance with one or more embodiments. Battery cell configuration 300 includes battery cell-1 302, battery cell-2 304, battery cell-3 306, and battery cell-4 308, each of which may be configured as any suitable type of battery. Additionally, each of battery cells 302 through 308 is configured with a respective parallel bulk capacitance 310 through 316 (e.g., super capacitor), which can be effective to mitigate a respective spike of current load on a given battery.

Each of battery cells 302 through 308 may provide (or receive) a respective amount of current from computing device 102, which are shown as current I₁ 318, current I₂ 320, current I₃ 322, and current I₄ 324. These individual currents are multiplexed via battery switching circuit 326 (switching circuit 326), the summation of which is current I_{Device} 328. Here, note that switching circuit 326 is but one example implementation of isolation circuitry 216 as described with respect to FIG. 2. In some cases, such as normal device operation, battery switching circuit 326 switches rapidly between battery cells 302 through 308 effective to draw current or power from each of them. In other cases, battery switching circuit 236 may isolate one of batteries 302 through 306 and switch between a subset of the remaining batteries to continue powering computing device 102.

FIG. 3 also illustrates example battery model 330, which may be used to model any battery cell or battery described herein. Generally, battery model 330 can be used to estimate or predict parameters of a battery that effect the battery's ability to provide power for computing device 102. In some cases, these battery parameters are dynamic and may not be directly observable or measurable by traditional sensing techniques. Battery model 330 includes an ideal voltage source that provides power and has an open circuit voltage 332 (V_{O} 332). When a battery is not providing current, an open circuit potential of the battery may be approximate to open circuit voltage 332.

Battery model 330 also includes direct current (DC) internal resistance 334 (R_{DCIR} 334), capacitance 336 (C 336), and concentration resistance 338 (R_{Conc.} 338). Battery current 340 (I 340) is formed by capacitance current (I_{C} 342) and concentration resistance current 338 (I_{R} 344), which are effected by capacitance 336 and concentration resistance 338, respectively. Battery voltage 346 (V 346) represents the terminal voltage for battery model 330 and can be effected by the losses associated with the other parameters, such as when current passes through concentration resistance 338 and internal resistance 334.

Example Methods

The methods described herein may be used separately or in combination with each other, in whole or in part. These methods are shown as sets of operations (or acts) performed, such as through one or more entities or modules, and are not necessarily limited to the order shown for performing the operation. For example, the techniques may estimate an internal resistance based on an amount of current drawn from, or applied to, a battery cell and measured instances of the battery cell's voltage. The techniques may also estimate a concentration resistance or capacitance based on an amount of current drawn from, or applied to, a battery cell and instances of the battery cell's voltage that are measured at particular times after the application of the current. These are but a few examples that may be implemented using the techniques described herein. In portions of the following discussion, reference may be made to the operating environment 100 of FIG. 1, the battery system 200 of FIG. 2, the battery cell configuration 300 of FIG. 3, and other methods and example embodiments described elsewhere herein, reference to which is made for example only.

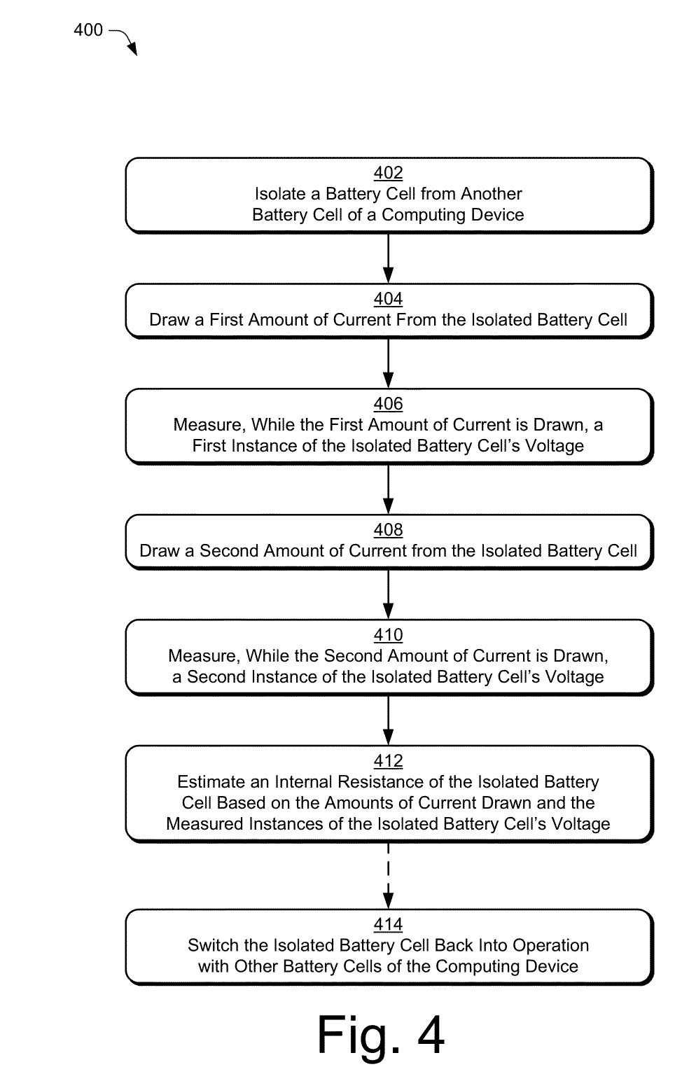

FIG. 4 depicts method 400 for estimating an internal resistance of a battery cell, including operations performed by battery manager 118 or parameter estimator 204.

At 402, a battery cell is isolated from another battery cell of a computing device. The battery cell may be isolated from the other battery cell with any suitable switching circuitry or isolation circuitry. It should be noted that isolation of the battery cell is optional and that other operations described herein may be performed using one or more un-isolated battery cells. In some cases, the battery cell is isolated from multiple other battery cells arranged in a parallel or series configuration (e.g., two series by four parallel or 2S4P). While the battery cell is isolated, the computing device may continue to draw operating current from, or apply charging current to, the other battery.

By way of example, consider battery cell configuration 300. Here, assume that battery cell configuration 300 is implemented in laptop computer 108, which is operating from battery power. When discharging the batteries, switching circuit 326 switches between battery cells 302 through 308 to draw current from each of the battery cells. Here, parameter estimator 204 isolates, via switching circuit 326, battery cell-1 302 from battery cells 304 through 308, which may continue to provide operational current to laptop computer 108.

At 404, a first amount of current is drawn the isolated battery cell. The first amount of current may be any suitable amount of current, such as a discharge current ranging from C amps to C/20 amps, where C is a capacity of the battery cell in amp-hours. In some cases, the first amount of current is based on a known amount of current consumed by components of the device at a particular activity level. For example, the amount of current may be current consumed while the device's CPU is at a highest power state and the device's display is at full brightness. Alternately, the first amount of current may be applied to the isolated battery cell. In some cases, the amount of current is applied in accordance with a constant-current charge profile. In such cases, the application of the first amount of current may be substantially stable and constant.

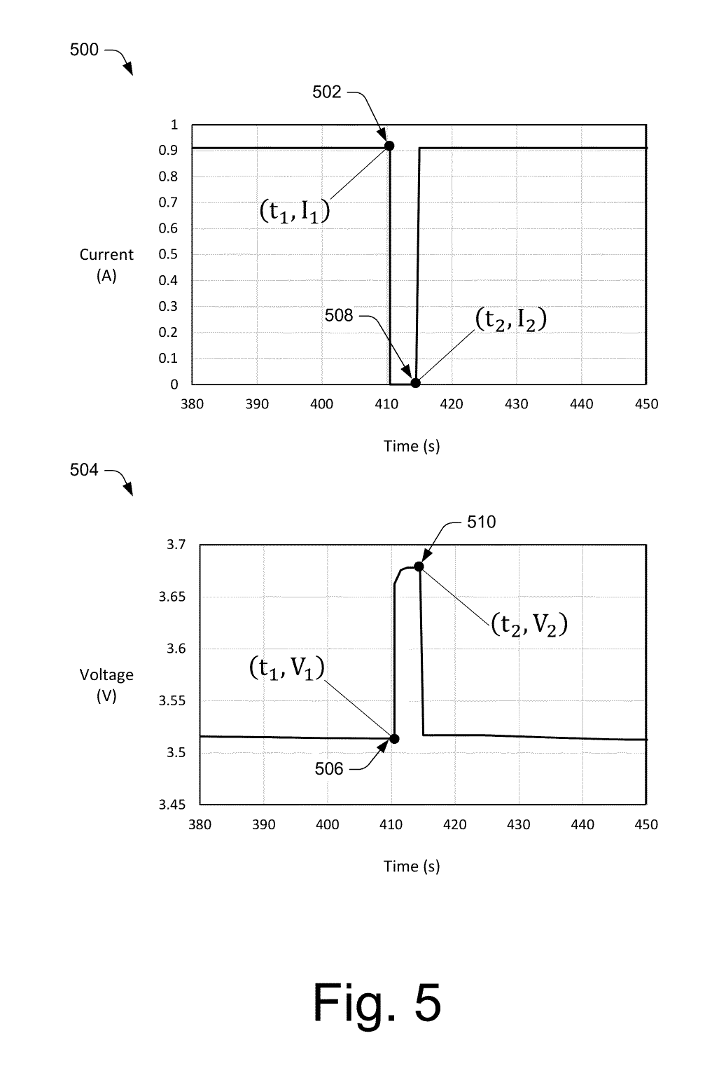

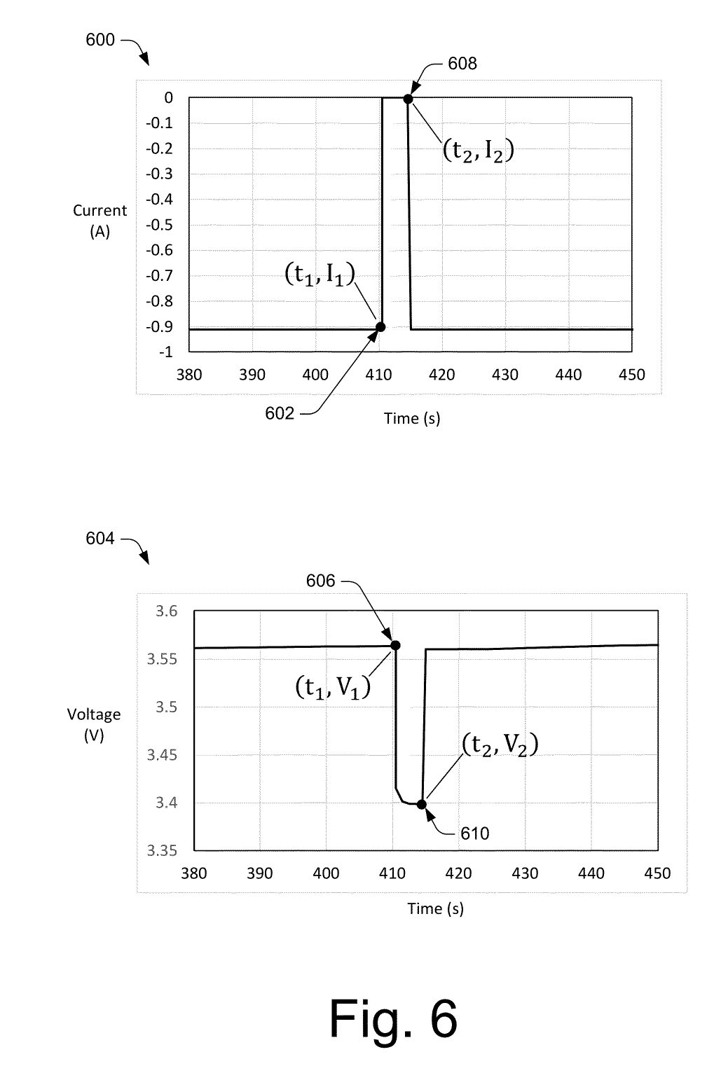

In the context of the present example and as illustrated by current graph 500 of FIG. 5, parameter estimator 204 draws, via isolation circuitry 216, current I₁ 502 (e.g., operational current) from battery cell-1 302. Although isolated from battery cells 304 through 308, switching circuit 326 switches between voltage regulation circuitry (not shown) and battery cell-1 302 to enable current I₁ 502 to be drawn from battery cell-1 302. Alternately, for cases in which current is applied to a battery cell, consider current graph 600 of FIG. 6. Here, parameter estimator 204 would apply, via charging circuitry 212, current I₁ 602 (charging current as denoted by negative values) to the battery cell.

At 406, a first instance of the isolated battery cell's voltage is measured while the first amount of current is drawn. The isolated battery cell's voltage may be measured at any point in time while the first amount of current is drawn. Continuing the ongoing example and as illustrated by voltage graph 504, parameter estimator 204 measures, via sensing circuitry 214, voltage V₁ 506 of battery cell-1 302 while current I₁ 502 is drawn. Alternately, a first instance of the isolated battery cell's voltage can be measured while a first amount of current is applied to the isolated battery. An example of this is illustrated by voltage graph 604, in which voltage V₁ 606 of the battery cell is measured while current I₁ 602 is applied.

At 408, a second amount of current is drawn from the isolated battery cell. The second amount of current may be any suitable amount that is different from the first amount of current, such as a different amount of discharge current consumed by components of the device. Alternately, the drawing of the first amount of current may be interrupted, effective to halt the discharge any current from the battery cell. The second amount of current is drawn for at least a particular amount of time, such as from approximately one second to approximately ten seconds. In the context of the present example, parameter estimator 204 interrupts the discharge of current I₁ 502 from battery cell-1 302 from time t₁ to time t₂, during which current I₂ 508 being drawn from battery cell-1 302 is approximately zero amps.

Alternately, a second amount of current can be applied to the isolated battery cell. The second amount of current may be any suitable amount that is different from the first amount of current, such as a different amount of charge current. Alternately, the application of the first amount of current may be interrupted, effective to halt the application any charging current to the battery cell. The second amount of current is applied for at least a particular amount of time, such as from approximately one second to approximately ten seconds. Returning to current graph 600, the application current I₁ 602 is interrupted from time t₁ to time t₂, during which current I₂ 608 applied to the battery cell is approximately zero amps.

At 410, a second instance of the isolated battery cell's voltage is measured while the second amount of current is drawn. Alternately, the second instance of voltage may be measured while no current is drawn, such as when discharging is interrupted. The isolated battery cell's voltage may be measured at any point in time while the second amount of current is drawn, or not drawn in the case of discharge interruption. In the context of the present example, parameter estimator 204 measures, via sensing circuitry 214, voltage V₂ 510 of battery cell-1 302 while current I₂ 508 is drawn.

In the alternate case of current application, a second instance of the isolated battery cell's voltage is measured while the second amount of current is applied. In some cases, the second instance of voltage is measured while no current is applied, such as when charging is interrupted. The isolated battery cell's voltage may be measured at any point in time while the second amount of current is applied, or not applied in the case of charge interruption. Returning to voltage graph 604, voltage V₂ 610 of the battery cell is measured while current I₂ 508 is applied.

At 412, an internal resistance of the isolated battery cell is estimated based on the amounts of current drawn and the measured instances of the voltage. Because the isolation circuitry or switching circuitry permits the isolation of the battery cell, other battery cells of the computing device may continue to charge or provide operating power while this and the other preceding operations are performed. Extending Ohm's Law to estimate the internal resistance (IR) of the isolated battery cell based on the values of FIG. 5 yields Equation 1.

$${V}_{1} - {V}_{2} = ( {I}_{1} - {I}_{2} ) IR \to IR = \frac{Δ V}{Δ I} \qquad Equation 1$$

Continuing the ongoing example, parameter estimator 204 applies V₁ 506, V₂ 510, I₁ 502, and I₂ 508 to Equation 1 to estimate an IR of battery cell-1 302. Parameter estimator 204 can then update a battery model of battery cell-1 302 with the estimated internal resistance. By so doing, battery manager 118 can predict an ability of battery cell-1 302 to provide current under various conditions.

Alternately, an internal resistance of the isolated battery cell can be estimated based on the amounts of current applied and the measured instances of the voltage. Extending Ohm's Law to estimate the IR of the isolated battery cell based on the values of FIG. 6 yields Equation 2.

$$\vert {V}_{1} - {V}_{2} \vert = ( \vert {I}_{1} - {I}_{2} \vert ) IR \to IR = \frac{Δ V}{Δ I} \qquad Equation 2$$

Optionally at 414, the isolated battery cell is switched back into operation with other battery cells of the computing device. In some cases, this may include switching the isolated battery cell back into circuit with the other battery cell of the computing device, which may be charging. Alternately, the isolated battery cell may be switched back in with the other battery cell to provide operating current for the computing device. Concluding the present example, parameter estimator combines, via switching circuit 326, battery cell-1 302 with battery cells 304 through 308, which may continue to charge or provide operational current to laptop computer 108.

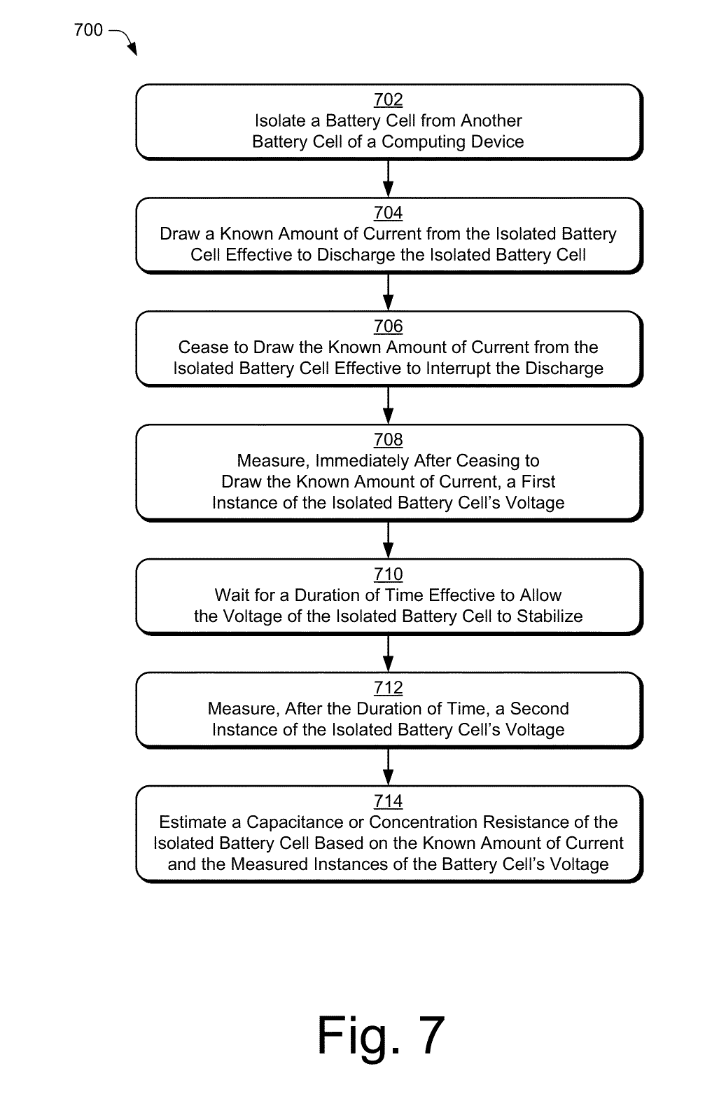

FIG. 7 depicts method 700 for estimating a capacitance or concentration resistance of a battery cell, including operations performed by battery manager 118 or parameter estimator 204.

At 702, a battery cell is isolated from another battery cell of a computing device. The battery cell may be isolated from the other battery cell with any suitable switching circuitry or isolation circuitry. In some cases, the battery cell is isolated from multiple other battery cells arranged in a parallel or series configuration. While the battery cell is isolated, the computing device may continue to draw operating current from, or apply charging current to, the other battery.

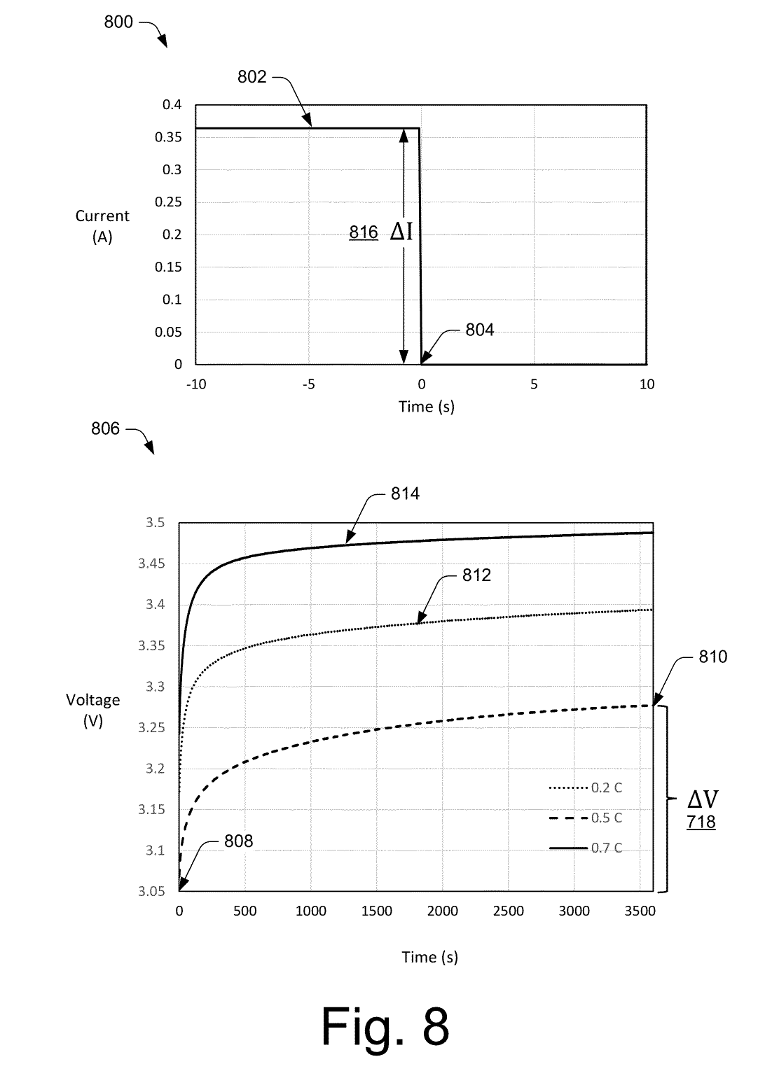

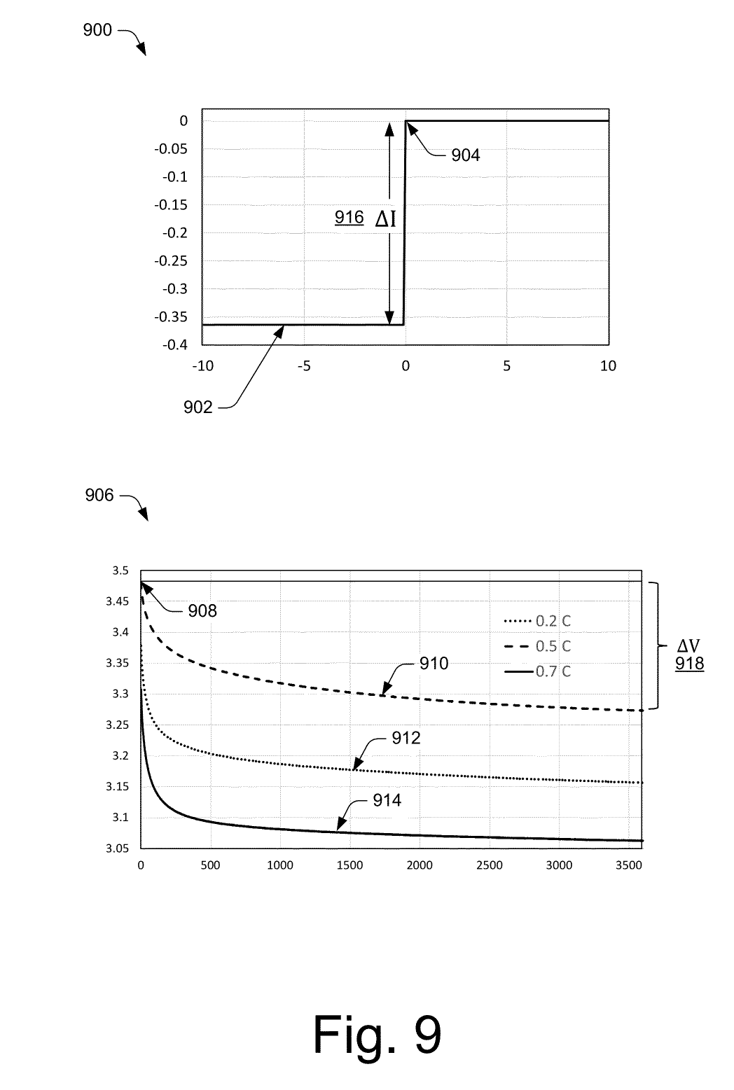

At 704, a known amount of current is drawn from the isolated battery cell effective to discharge the isolated battery cell. The known amount of current may be any suitable amount of current, such as current consumed by components of the computing device. By way of example, consider current graph 800 of FIG. 8 in which current 702 is drawn from an isolated battery cell. Here, assume that current 802 comprises approximately 375 mA of current drawn from the isolated battery cell by setting components of a device to known states (e.g., display to full brightness). Alternately, a known amount of current can be applied to isolated battery cell, such as charging current. In some cases, the known amount of current is based on a constant-current charging profile of the battery cell. An example of this alternate case illustrated by current graph 900 of FIG. 9, in which current 902 is applied to the battery cell (charging denoted by negative current values).

At 706, the drawing of the known amount of current is ceased effective to interrupt discharge of the isolated battery cell. In some cases, drawing of the current is ceased by switching the isolated battery cell out of a discharge circuit. This can be effective to allow a voltage of the isolated battery cell to stabilize or relax. In the context of discharging current from a battery cell, the discharge of current 802 is halted at time 804, which is located at zero seconds on the time axis of current graph 800. In the alternate case of applying current, the application of the current can be ceased effective to interrupt the charging of the isolated battery cell. Returning to current graph 900, the application of current 902 is halted at time 904, which is located at zero seconds on the time axis of current graph 900.

At 708, a first instance of the isolated battery cell's voltage is measured after ceasing to draw the current. This first instance of the voltage may be measured immediately after ceasing to draw the current from the isolated battery cell. As shown in voltage graph 806, voltage 808 is measured at the terminal of the battery cell at time zero after the discharge of current 802 is interrupted. Alternately, a first instance of the isolated battery cell's voltage can be measured after ceasing to apply the known amount of current. An example of this is illustrated by voltage graph 906, in which voltage 908 (e.g., terminal voltage) is measured at time zero after interrupting the application of current 902.

At 710, a duration of time is waited effective to allow the voltage of the isolated battery cell to stabilize. Waiting for longer durations of time may allow for a more-accurate measurement of the isolated battery cell's change in voltage. In some cases, the duration of time waited ranges from 120 seconds to an hour after charging is interrupted. In other cases, the duration of time is much shorter, such as approximately 60 seconds to 120 seconds. In the context of the present example, assume the amount of time waited is 3500 seconds, or approximately 58 minutes, as shown in voltage graph 806 or 906.

At 712, a second instance of the isolated battery cell's voltage is measured after waiting for the duration of time. As noted at operation 710, the duration of time may range from 60 to 120 seconds, or up to an hour or more. Continuing the ongoing example, voltage 810 is measured after waiting 3500 seconds from ceasing to discharge current 802. As additional examples, voltage profile 812 and voltage profile 814 illustrate voltage relaxation associated with discharge rates of 0.2 C and 0.7 C respectively.

In the alternate case of applying current to the battery cell, a second instance of voltage may also be measured after waiting for the durations of time as described with respect to operation 712. Here, voltage 910 is measured after waiting 3500 seconds from ceasing the application of charging current 902. As additional examples, voltage profile 912 and voltage profile 914 illustrate voltage relaxation associated with charge rates of 0.2 C and 0.7 C respectively

At 714, a capacitance or concentration resistance of the isolated battery cell is estimated based on the known amount of current and the measured instances of the voltage. In cases in which the voltage of the isolated battery cell is provided ample time to relax (e.g., ˜1 hour), concentration resistance may be calculated using Equation 3.

$${R}_{Concentration} = \frac{Δ V}{Δ I} \qquad Equation 3$$

In the context discharging current, concentration resistance of the isolated battery cell can be determined from current 802, voltage 808, and voltage 810. Here, these values for use in Equation 3 are illustrated in FIG. 8 as ΔI 816 and ΔV 818. In the case of charging current, concentration resistance can be calculated using similar value of FIG. 9, which are shown as ΔI 916 and ΔV 918.

In some embodiments, a relaxed voltage or steady-state potential of an isolated battery cell may be predicted from data collected over shorter durations of time. In some cases, this can be effective to accurately estimate concentration resistance or capacitance without having to wait for voltage of a battery cell to fully relax or stabilize. In such cases, concentration resistance or capacitance may be estimated based on data collected over as few as 60 seconds, 120 seconds, or 600 seconds.

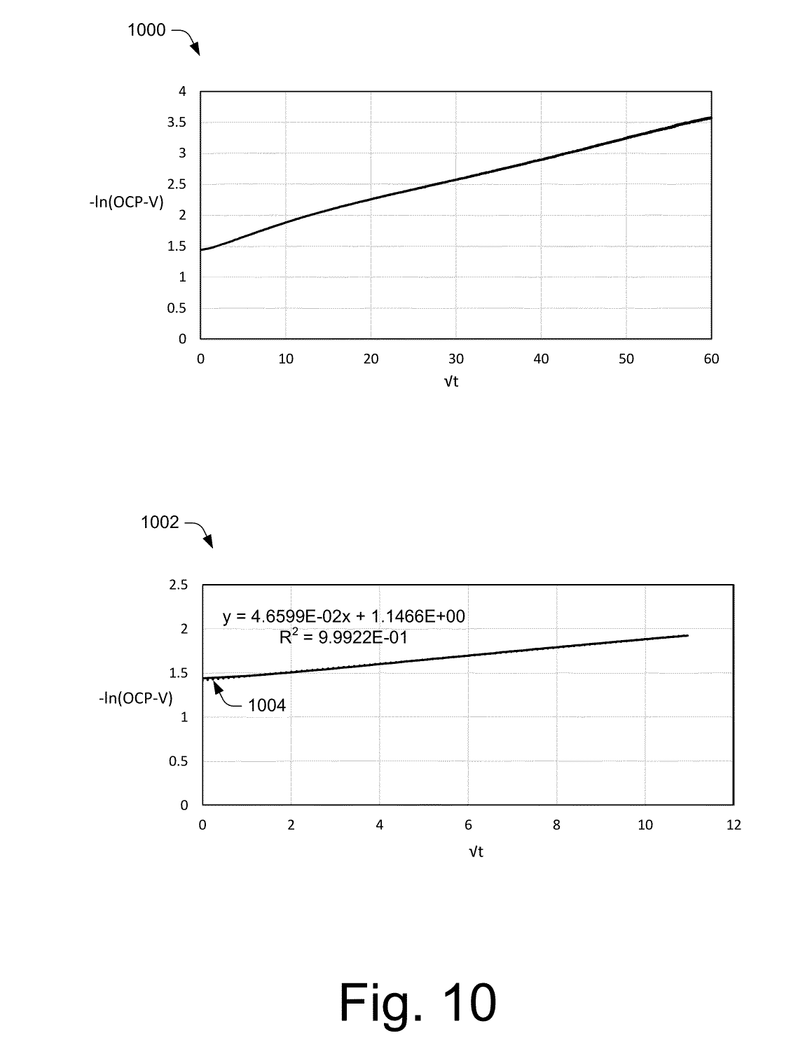

Steady state potential of the battery cell can be estimated by linearizing a voltage (open circuit potential (OCP)) relaxation curve and fitting (A and B values) the linearization as shown in Equation 4, which may be applied to values associated with discharging battery cells. A graphical representation of Equation 4 is illustrated in FIG. 10 at 1000, which shows a log of potential vs. the square root of time.

−ln(OCP−V)=A\sqrt{t}+B Equation 4

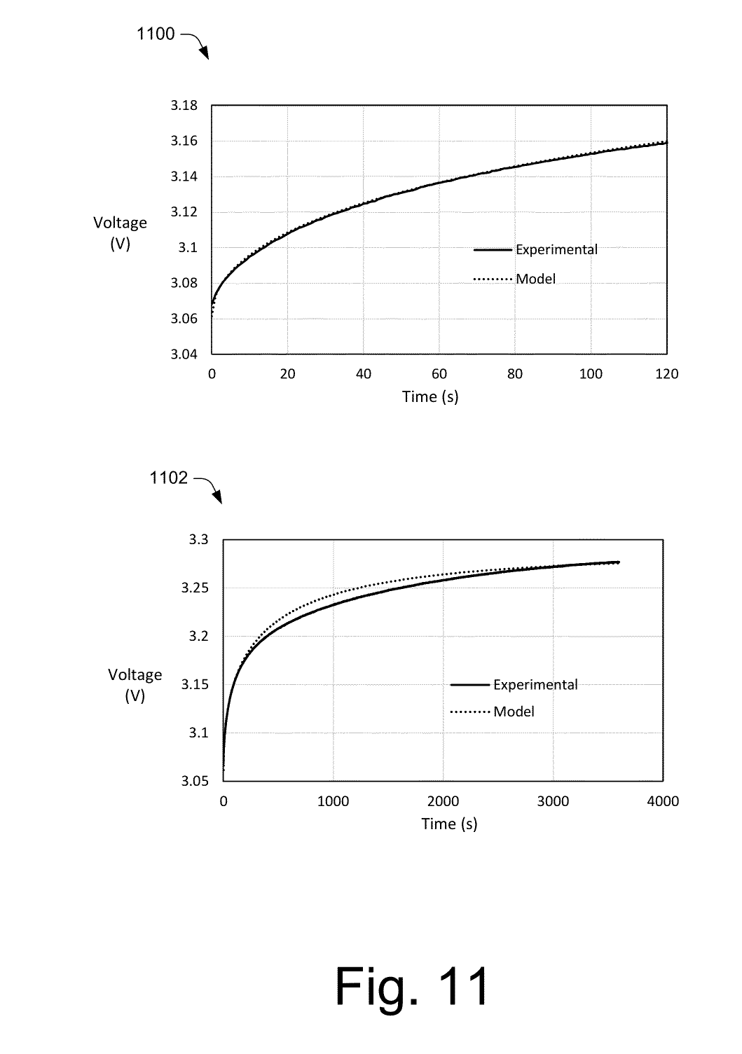

Because OCP is not accurately known, an estimation for OCP can be made by altering OCP to maximize R² as shown at 1002, which includes a fit with experimental results 1004. Further, from this fit model and as illustrated in FIG. 11, a comparison can be made between results of the fit model and experimental data as shown in voltage graph 1100. Here, notice that within 120 seconds, the model fits well with the experimental results. Extrapolating the comparison to one hour, however, may result in a slight increase in error as shown in voltage graph 1102.

With a model capable of estimating OCP, concentration resistance can also be found using Equation 5.

$$\frac{OCP - {V}_{0}}{Δ I} = {R}_{Concentration} \qquad Equation 5$$

Capacitance of the battery cell can also be determined by finding a time constant for Equation 4, which can be solved for and written as Equation 6 as shown below.

$$Att = 0 , V = {V}_{0} \\ Att = {t}_{1} = τ , V = {V}_{1} \\ {V}_{1} = ( 1 - \frac{1}{e} ) ( OCP - {V}_{0} ) + {V}_{0} \\ τ = {( \frac{- ln ( OCP - {V}_{1} ) - B}{A} )}^{2} \\ τ = C * IR \\ C = \frac{τ}{IR} \qquad Equation 6$$

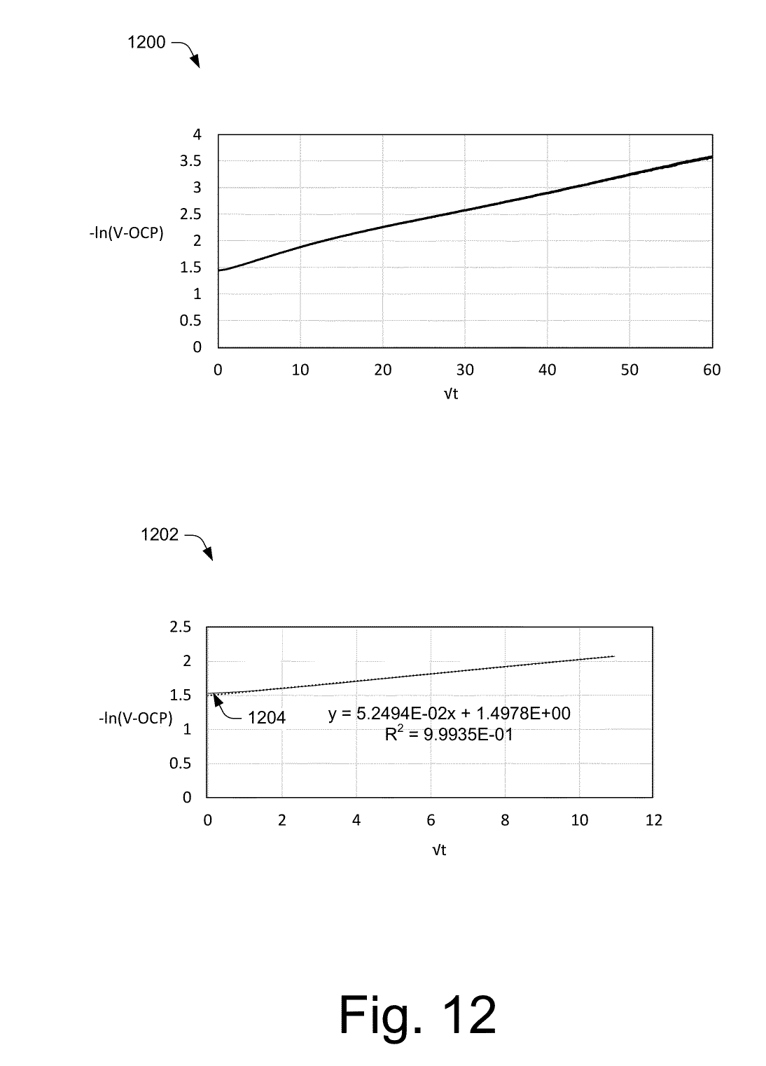

In the alternate case of applying current to a battery cell, steady state potential of the battery cell may be estimated by performing a similar linearization, which is shown in Equation 7. A graphical representation of Equation 7 is illustrated in FIG. 12 at 1200, which shows a log of potential vs. the square root of time.

−ln(V−OCP)=A\sqrt{t}+B Equation 7

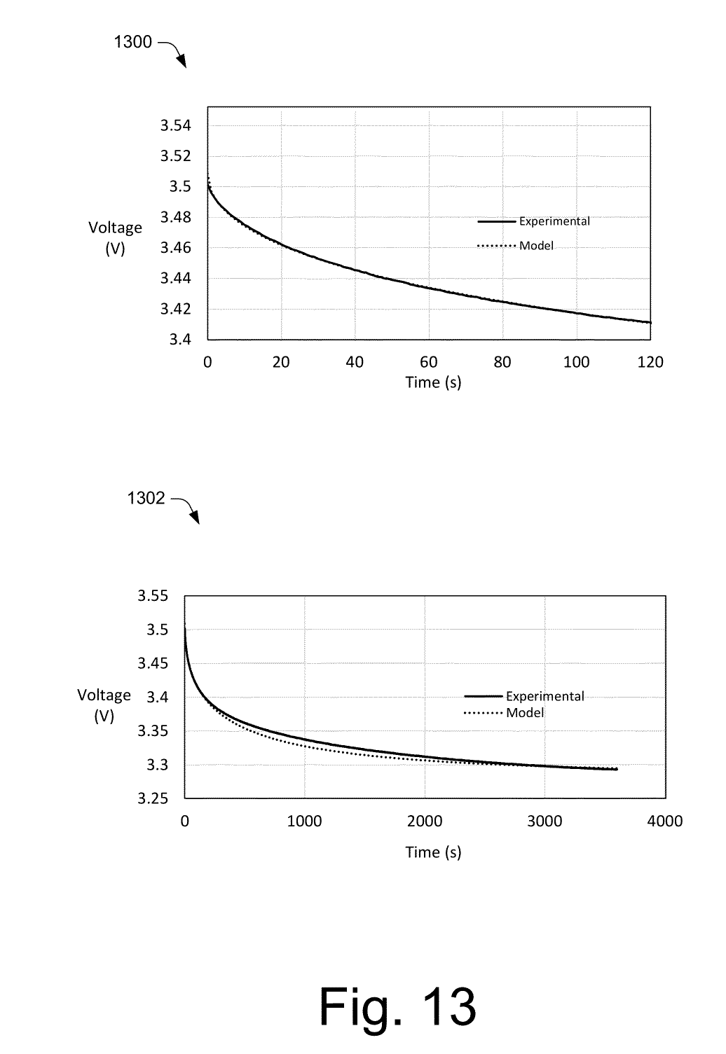

An estimation for OCP can be made by altering OCP to maximize R² as shown at 1202, which includes a fit with experimental results 1204. Further, from this fit model and as illustrated in FIG. 13, a comparison can be made between results of the fit model and experimental data as shown in voltage graph 1300. Here, notice that within 120 seconds, the model fits well with the experimental results. Extrapolating the comparison to one hour, however, may result in a slight increase in error as shown in voltage graph 1302.

With a model capable of estimating OCP, concentration resistance can also be found using Equation 8.

$$\frac{{V}_{0} - OCP}{Δ I} = {R}_{Concentration} \qquad Equation 8$$

Capacitance of the battery cell can also be determined by finding a time constant for Equation 7, which can be solved for and written as Equation 9 as shown below.

$$Att = 0 , V = {V}_{0} \\ Att = {t}_{1} = τ , V = {V}_{1} \\ {V}_{1} = ( 1 - \frac{1}{e} ) ( {V}_{0} - OCP ) \\ τ = {( \frac{- ln ( {V}_{1} - OCP ) - B}{A} )}^{2} \\ τ = C * IR \\ C = \frac{τ}{IR} \qquad Equation 9$$

Accordingly, the capacitance or concentration resistance of the isolated battery cell can be estimated with the model described herein. By so doing, a duration of time for which discharging or charging is interrupted can be minimalized. Once the capacitance or concentration resistance is estimated, method 700 may optionally switch the isolated battery cell back into circuit with other battery cells of the computing device.

Once internal resistance, capacitance, or concentration resistance are estimated for a battery cell, a model of the battery cell can be constructed or updated with the estimated values. By so doing, performance (present or future) of the battery cell can be more-accurately predicted. In some cases, the model of the battery cell can be leveraged to enable more efficient use of the battery cell.

For example, battery manager 118 can estimate future battery performance based on a model and a state-of-charge of a battery cell. Using information provided by current load monitor 206 and workload estimator 208, battery manager 118 can predict how the battery cell will perform under different loads (e.g., an ability to provide current). Based on the predicted performance of the battery cells, load allocator 210 can then optimally distribute system current draw across one or more of the battery cells to maximize battery efficiency or minimize internal battery losses associated with the parameters described herein.

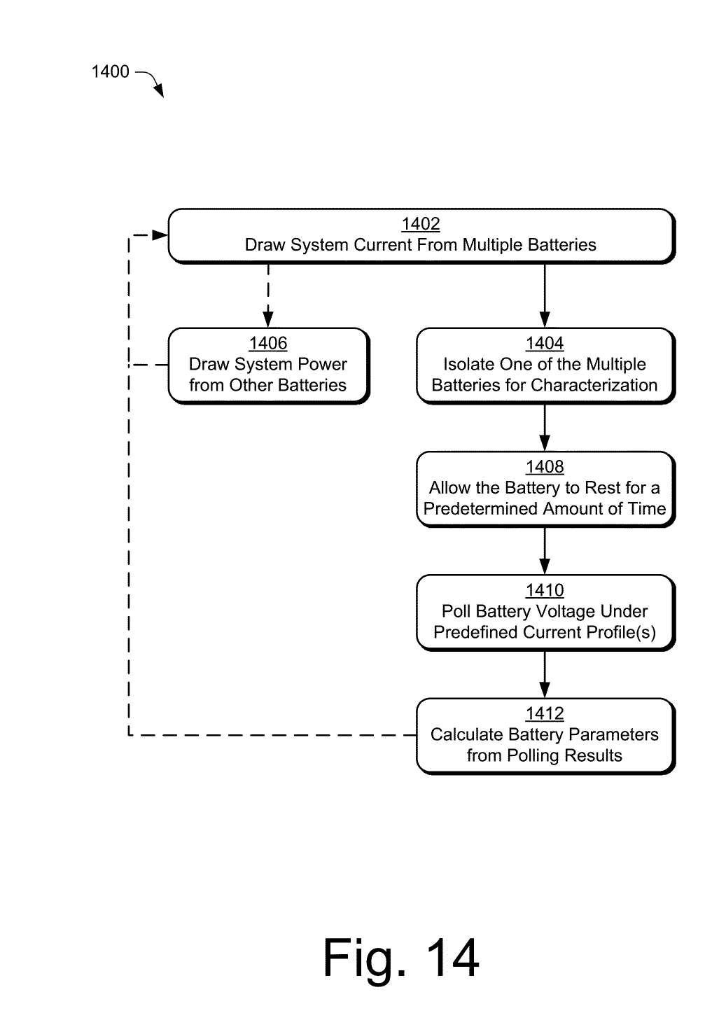

FIG. 14 depicts method 1400 for calculating battery parameters for multiple batteries, including operations performed by battery manager 118 or battery monitor 202.

At 1402, system current of a computing device is drawn from multiple batteries of the computing device. The multiple batteries may be configured as a homogeneous combination of batteries or a heterogeneous combination of batteries having different chemistry types or different capacities. Alternately, charging current may be applied to the multiple batteries of the computing device.

At 1404, one of the multiple batteries is isolated from the multiple batteries for parameter characterization. The battery may be isolated by any suitable switching or isolation circuitry. In some cases, the battery is isolated from other batteries in series and other batteries in parallel. Alternately or additionally, the battery may be isolated from bulk capacitance connected in parallel with the battery.

Optionally at 1406 and while the battery is isolated, system current continues to be drawn from the other multiple batteries by which the computing device operates. Alternately, charging current may be applied to the other multiple batteries while the battery is isolated.

At 1408, the battery is allowed to rest for a predetermined amount of time. This can be effective to permit properties of the battery to stabilize, such as temperature, voltage, and the like.

At 1410, voltage of the battery is polled under the discharge or application of predefined current profiles. The predefined current profiles may include varying amounts of current or an interruption in the discharge or application of current, such as those described herein. In some cases, a predefined current profile may be configured to enable a particular battery parameter to be calculated, such as internal resistance, capacitance, or concentration resistance.

At 1412, parameters for the battery are calculated based on results of the polling. The results of the polling may include multiple voltage measurements made at particular points during application of a predefined current profile. From operation 1412, method 1400 may return to operation 1402 in order to calculate parameters of another one of the multiple batteries of the computing device.

Aspects of these methods may be implemented in hardware (e.g., fixed logic circuitry), firmware, a System-on-Chip (SoC), software, manual processing, or any combination thereof. A software implementation represents program code that performs specified tasks when executed by a computer processor, such as software, applications, routines, programs, objects, components, data structures, procedures, modules, functions, and the like. The program code can be stored in one or more computer-readable memory devices, both local and/or remote to a computer processor. The methods may also be practiced in a distributed computing environment by multiple computing devices.

Example Device

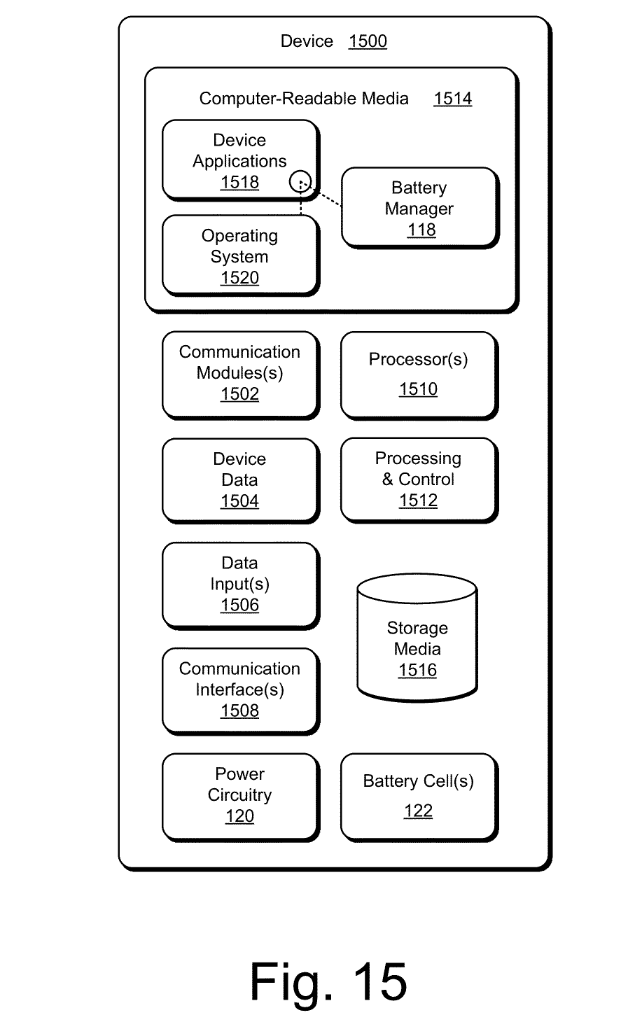

FIG. 15 illustrates various components of example device 1500 that can be implemented as any type of mobile, electronic, and/or computing device as described with reference to the previous FIGS. 1-10 to implement techniques of estimating battery cell parameters. In embodiments, device 1500 can be implemented as one or a combination of a wired and/or wireless device, as a form of television client device (e.g., television set-top box, digital video recorder (DVR), etc.), consumer device, computer device, server device, portable computer device, user device, communication device, video processing and/or rendering device, appliance device, gaming device, electronic device, and/or as another type of device. Device 1500 may also be associated with a user (e.g., a person) and/or an entity that operates the device such that a device describes logical devices that include users, software, firmware, and/or a combination of devices.

Device 1500 includes communication modules 1502 that enable wired and/or wireless communication of device data 1504 (e.g., received data, data that is being received, data scheduled for broadcast, data packets of the data, etc.). Device data 1504 or other device content can include configuration settings of the device, media content stored on the device, and/or information associated with a user of the device. Media content stored on device 1500 can include any type of audio, video, and/or image data. Device 1500 includes one or more data inputs 1506 via which any type of data, media content, and/or inputs can be received, such as user-selectable inputs, messages, music, television media content, recorded video content, and any other type of audio, video, and/or image data received from any content and/or data source.

Device 1500 also includes communication interfaces 1508, which can be implemented as any one or more of a serial and/or parallel interface, a wireless interface, any type of network interface, a modem, and as any other type of communication interface. Communication interfaces 1508 provide a connection and/or communication links between device 1500 and a communication network by which other electronic, computing, and communication devices communicate data with device 1500.

Device 1500 includes one or more processors 1510 (e.g., any of microprocessors, controllers, and the like), which process various computer-executable instructions to control the operation of device 1500 and to enable techniques for estimating battery cell parameters. Alternatively or in addition, device 1500 can be implemented with any one or combination of hardware, firmware, or fixed logic circuitry that is implemented in connection with processing and control circuits which are generally identified at 1512. Although not shown, device 1500 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures. Device 1500 may be configured to operate from any suitable power source, such as battery cells 122, power circuitry 120, various external power sources, and the like.

Device 1500 also includes computer-readable storage media 1514, such as one or more memory devices that enable persistent and/or non-transitory data storage (i.e., in contrast to mere signal transmission), examples of which include random access memory (RAM), non-volatile memory (e.g., any one or more of a read-only memory (ROM), flash memory, EPROM, EEPROM, etc.), and a disk storage device. A disk storage device may be implemented as any type of magnetic or optical storage device, such as a hard disk drive, a recordable and/or rewriteable compact disc (CD), any type of a digital versatile disc (DVD), and the like. Device 1500 can also include a mass storage media device 1516.

Computer-readable storage media 1514 provides data storage mechanisms to store device data 1504, as well as various device applications 1518 and any other types of information and/or data related to operational aspects of device 1500. For example, an operating system 1520 can be maintained as a computer application with the computer-readable storage media 1514 and executed on processors 1510. Device applications 1518 may include a device manager, such as any form of a control application, software application, signal-processing and control module, code that is native to a particular device, a hardware abstraction layer for a particular device, and so on.

Device applications 1518 also include any system components or modules to implement the techniques, such as battery manager 118 and any combination of components thereof.

### CONCLUSION

Although embodiments of techniques and apparatuses of estimating of battery cell parameters have been described in language specific to features and/or methods, it is to be understood that the subject of the appended claims is not necessarily limited to the specific features or methods described. Rather, the specific features and methods are disclosed as example implementations of estimating battery cell parameters.

What is claimed is:

1. A computer-implemented method comprising:
drawing a first amount of current from a battery cell of a computing device;
measuring, while the first amount of current is drawn, a first instance of the battery cell's voltage;
drawing a second amount of current from the battery cell;
measuring, while the second amount of current is drawn, a second instance of the battery cell's voltage; and
estimating an internal resistance of the battery cell based on the first and second amounts of current drawn from the battery cell and the first and second instances of the battery cell's voltage.

2. The computer-implemented method as described in claim 1, further comprising, prior to drawing the first amount or second amount of current, isolating the battery cell from another battery cell of the computing device.

3. The computer-implemented method as described in claim 1, wherein the second amount of current is approximately zero amps of current.

4. The computer-implemented method as described in claim 1, wherein the second amount of current is drawn from the battery cell for approximately one to ten seconds.

5. The computer-implemented method as described in claim 1, wherein the computing device is operating on power drawn from the battery cell or other battery cells while the acts of drawing and measuring are performed.

6. The computer-implemented method as described in claim 1, wherein a chemistry of the battery cell is different from a chemistry of another battery cell of the device.

7. The computer-implemented method as described in claim 1, wherein a capacity of the battery cell is different from a capacity of another battery cell of the device.

8. The computer-implemented method as described in claim 1, further comprising estimating, based on the internal resistance of the battery, an ability of the battery to provide power to the device.

9. A computer-implemented method comprising:
drawing a known amount of current from a battery cell of a computing device effective to discharge the battery cell;
ceasing to draw the known amount of current from the battery cell effective to interrupt discharging of the battery cell;
measuring, at a first point in time immediately after ceasing to draw the known amount of current, a first instance of the battery cell's voltage;
measuring, at a second point in time that follows the first point in time, a second instance of the cell's voltage; and
estimating a capacitance or concentration resistance of the battery cell based on at least the known amount of current and the first and second instances of the battery cell's voltage.

10. The computer-implemented method as described in claim 9, wherein the second point in time occurs approximately 60 to 120 seconds after the first period of time.

11. The computer-implemented method as described in claim 9, further comprising, prior to drawing the know amount of current, isolating the battery cell from another battery cell of the computing device.

12. The computer-implemented method as described in claim 9, wherein the computing device is operating on power drawn from the battery cell or another battery cell of the device while the acts of drawing, ceasing, and measuring are performed.

13. The computer-implemented method as described in claim 9, wherein a chemistry of the battery cell is different from a chemistry of another battery cell of the device.

14. The computer-implemented method as described in claim 9, wherein a capacity of the battery cell is different from a capacity of another battery cell of the device.

15. The computer-implemented method as described in claim 9, further comprising estimating, based on the capacitance or concentration resistance of the battery, an ability of the battery to provide power to the device.

16. A system comprising:
multiple battery cells from which the system draws current to operate;
switching circuitry configured to enable current to be drawn from or applied to each of the multiple battery cells;
sensing circuitry configured to measure respective voltage levels of the multiple battery cells of the system; and
a battery parameter estimator configured to perform operations comprising:
isolating, via the switching circuitry, a battery cell from the multiple battery cells of the system;
drawing, via the switching circuitry, a first amount of current from the isolated battery cell;
measuring, via the sensing circuitry and while the first amount of current is drawn, a first voltage level of the isolated battery cell;
drawing, via the switching circuitry, a second amount of current from the isolated battery cell;
measuring, via the sensing circuitry and while the second amount of current is drawn, a second voltage level of the isolated battery cell; and
estimating an internal resistance of the isolated battery cell based on the first and second amounts of current drawn from the isolated battery cell and the first and second voltage levels of the isolated battery cell.

17. The system as described in claim 16, wherein the second amount of current is drawn from the isolated battery cell for approximately one to ten seconds.

18. The system as described in claim 16, wherein the computing device is operating on power drawn from the isolated battery cell or others of the multiple battery cells while the acts of drawing and measuring are performed.

19. The system as described in claim 16, wherein a chemistry of the isolated battery cell is different from a respective capacity of at least one other of the multiple battery cells.

20. The system as described in claim 16, wherein a capacity of the isolated battery cell is different from a respective capacity of at least one other of the multiple battery cells.
